(19) United States
(12) Patent Application Publication
(10) Pub. No.: US 2026/0247942 A1
(43) Pub. Date: Aug. 20, 2026

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventor: Ryohei HASEGAWA, Kyoto-shi (JP)

(21) Appl. No.: 19/642,307

(22) Filed: Apr. 8, 2026

Related U.S. Application Data
(63) Continuation of application No. PCT/JP2024/034778, filed on Sep. 27, 2024.

(30) Foreign Application Priority Data
Oct. 18, 2023 (JP) 2023-179500

(51) Int. Cl. H10W 20/41; H10W 74/10

(52) U.S. Cl. CPC H10W 20/41; H10W 74/111

(57) ABSTRACT

A semiconductor device includes terminals, a semiconductor chip mounted on the terminals; and an encapsulation resin encapsulating the terminals and the semiconductor chip. The terminals each include a terminal portion and a mount portion. The terminal portion is located outward from the semiconductor chip. The mount portion extends from the terminal portion toward the semiconductor chip as viewed in the thickness-wise direction. The semiconductor chip is mounted on the mount head surface. The semiconductor device includes a cover layer contacting at least one of the mount head surface of the mount portion and the terminal head surface of the terminal portion. The cover layer has a lower linear expansion coefficient than the terminals.

### CROSS-REFERENCE TO RELATED APPLICATIONS

This application is a continuation of, and claims the benefit of priority from International Application No. PCT/JP2024/034778, filed on September 27, 2024, which claims the benefit of priority from Japanese Patent Application No. 2023-179500, filed on October 18, 2023, the entire contents of each are incorporated herein by reference.

### BACKGROUND

### 1. Field

The following description relates to a semiconductor device and a method for manufacturing a semiconductor device.

### 2. Description of Related Art

JP2020-188083A discloses a semiconductor device that includes a lead frame, a semiconductor element including pillars soldered to the lead frame, and a resin encapsulating the semiconductor element.

### BRIEF DESCRIPTION OF THE DRAWINGS

FIG. 1 is a schematic perspective view of a semiconductor device in accordance with an embodiment.

FIG. 2 is a schematic plan view showing the internal structure of the semiconductor device shown in FIG. 1.

FIG. 3 is a schematic back view of the semiconductor device shown in FIG. 1.

FIG. 4 is a schematic cross-sectional view of the semiconductor device taken along line F4-F4 shown in FIG. 2.

FIG. 5 is a schematic cross-sectional view of the semiconductor device taken along line F5-F5 shown in FIG. 4.

FIG. 6 is a schematic plan view of terminals and a cover layer.

FIG. 7 is a schematic plan view illustrating an exemplary manufacturing step of the semiconductor device in accordance with the embodiment.

FIG. 8 is a schematic cross-sectional view of a lead frame and the cover layer taken along line F8-F8 shown in FIG. 7, illustrating a manufacturing step following the step of FIG. 7.

FIG. 9 is a schematic cross-sectional view illustrating a manufacturing step following the step of FIG. 8.

FIG. 10 is a schematic plan view illustrating a manufacturing step following the step of FIG. 9.

FIG. 11 is a schematic plan view illustrating a manufacturing step following the step of FIG. 10.

FIG. 12 is a schematic cross-sectional view of the semiconductor device taken along line F12-F12 shown in FIG. 11, illustrating a manufacturing step following the step of FIG. 11.

FIG. 13 is a schematic cross-sectional view illustrating a manufacturing step following the step of FIG. 12.

FIG. 14 is a schematic cross-sectional view illustrating a step of mounting a semiconductor chip on the lead frame.

FIG. 15 is a schematic cross-sectional view of a semiconductor device of a modified example.

FIG. 16 is a schematic cross-sectional view of a semiconductor device of another modified example.

FIG. 17 is a schematic cross-sectional view enlarging part of a semiconductor device of another modified example.

FIG. 18 is a schematic cross-sectional view illustrating an exemplary manufacturing step of a semiconductor device of another modified example.

FIG. 19 is a schematic cross-sectional view illustrating a manufacturing step following the step of FIG. 18.

FIG. 20 is a schematic cross-sectional view illustrating a manufacturing step following the step of FIG. 19.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a semiconductor device and a method for manufacturing a semiconductor device according to the present disclosure will now be described with reference to the accompanying drawings. Elements in the drawings may not be drawn to scale for simplicity and clarity of illustration. In the cross-sectional drawings, hatching lines may not be shown in order to facilitate understanding. The accompanying drawings merely illustrate exemplary embodiments of the present disclosure and are not intended to limit the present disclosure.

This detailed description includes exemplary embodiments of devices, systems, and methods in accordance with the present disclosure. The present description is illustrative and is not intended to limit the embodiments of the present disclosure or application and use of the embodiments.

In this specification, the phrase “at least one of” as used in this disclosure means “one or more” of desired options. In an example, the phrase “at least one of” means “only one of two options” or “both of two options” if the number of options is two. In another example, the phrase “at least one of” means “only one of the options” or “any combination of two or more of the options” if the number of options is three or more.

In this specification, phrases such as “the length (dimension) of A is equal to the length (dimension) of B” and “A and B are equal in length (dimension)” includes a relationship in which the difference between the length (dimension) of A and the length (dimension) of B is, for example, within 10% of the length (dimension) of A.

### Embodiment

### Structure of Semiconductor Device

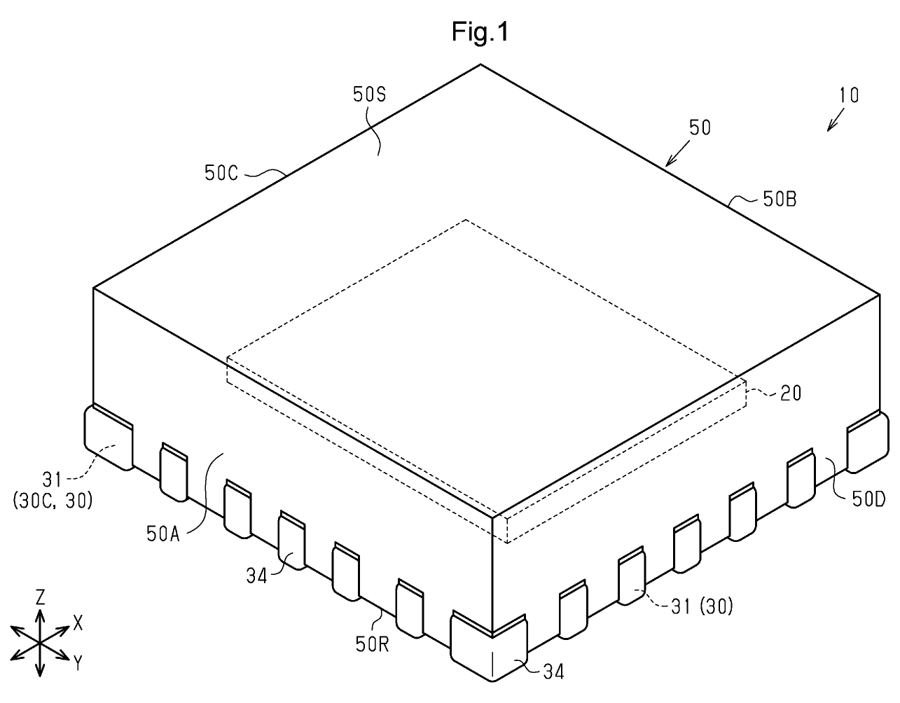

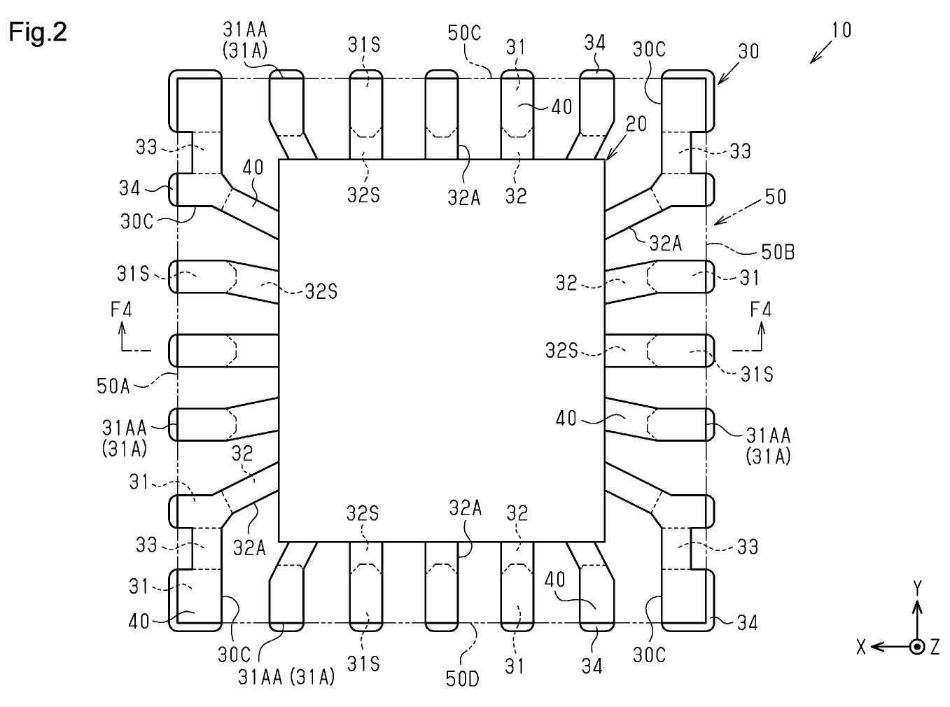

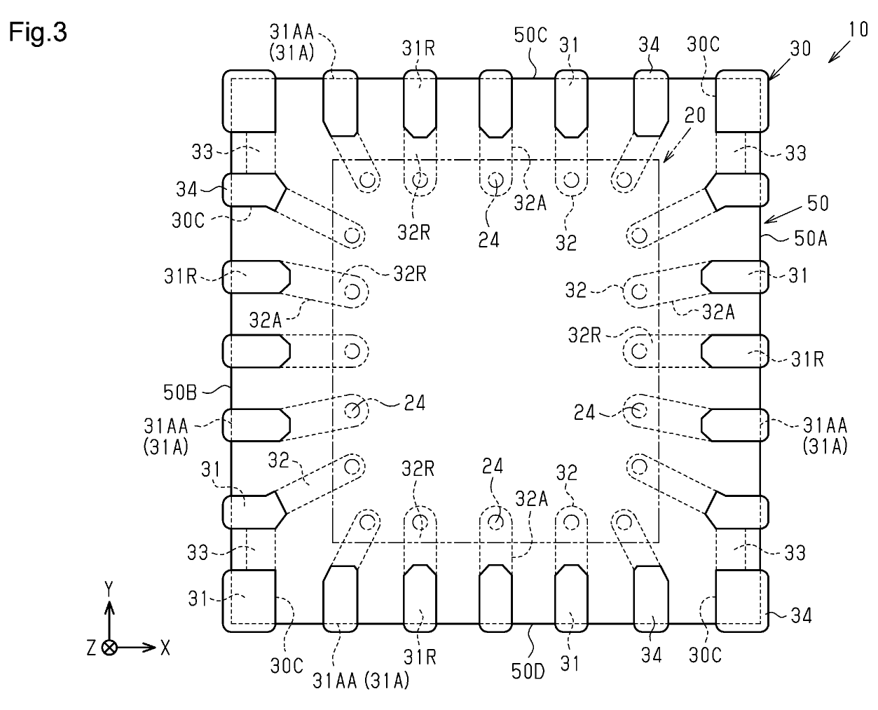

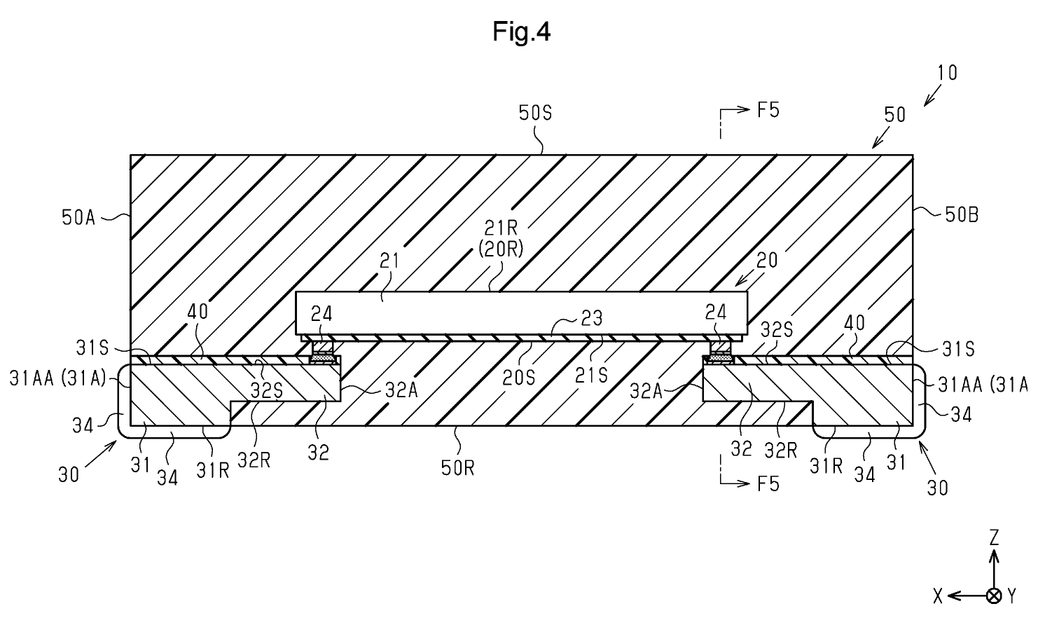

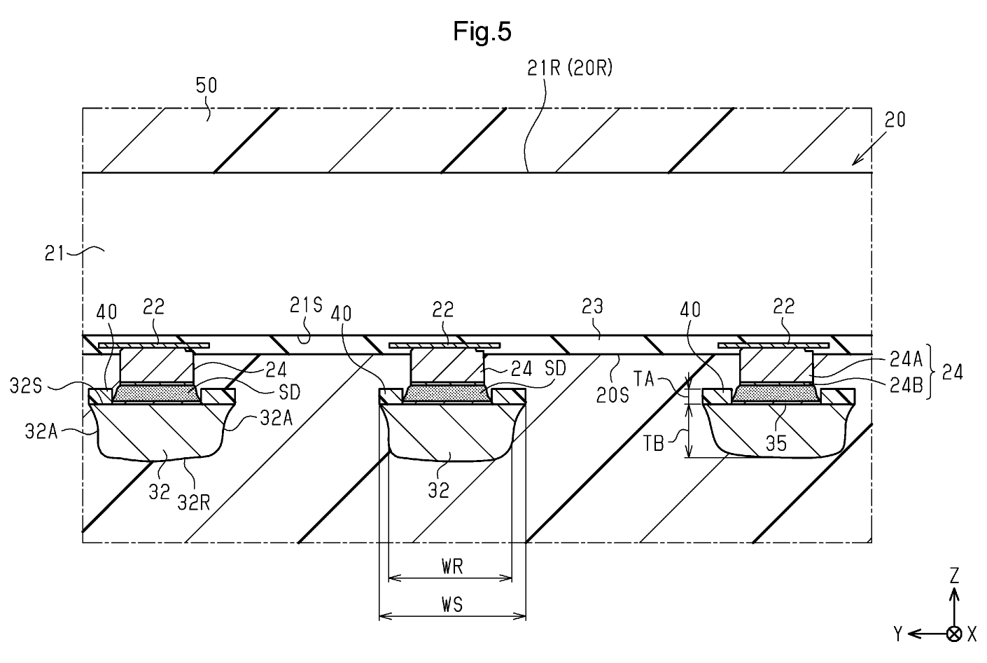

The overall structure of a semiconductor device 10 in accordance with an embodiment will now be described with reference to FIGS. 1 to 5. FIG. 1 is a schematic perspective view showing the structure of the semiconductor device 10. FIG. 2 is a schematic plan view showing the internal structure of the semiconductor device 10. FIG. 3 is schematic back view showing the structure of the semiconductor device 10. FIG. 4 is a schematic cross-sectional view taken along line F4-F4 shown in FIG. 2, showing the structure of the semiconductor device 10. FIG. 5 is a schematic cross-sectional view taken along line F5-F5 shown in FIG. 2, showing the structure of the semiconductor device 10. In FIG. 1, broken lines indicate a semiconductor chip 20, which will be described later. In FIG. 2, double-dashed lines indicate an encapsulation resin 50, which will be described later. In FIG. 3, double-dashed lines indicate the semiconductor chip 20. In this specification, X-axis, Y-axis, and Z-axis are orthogonal to one another as shown in FIG. 1. The term “plan view” as used in this disclosure refers to a view of the semiconductor device 10 or elements of the semiconductor device 10 taken in the Z-direction.

As shown in FIGS. 1 and 4, the semiconductor device 10 includes the semiconductor chip 20, terminals 30, cover layers 40, and the encapsulation resin 50. The semiconductor chip 20 is mounted on the terminals 30. The encapsulation resin 50 encapsulates the semiconductor chip 20, the terminals 30, and the cover layers 40.

The encapsulation resin 50 defines a device head surface, a device back surface, and device side surfaces of the semiconductor device 10. The encapsulation resin 50 has a rectangular plate shape and has a thickness-wise direction parallel to the Z-direction. In other words, the semiconductor device 10 has a rectangular plate shape and has a thickness-wise direction parallel to the Z-direction.

The encapsulation resin 50 includes an encapsulation head surface 50S, an encapsulation back surface 50R, and four encapsulation side surfaces 50A to 50D. The encapsulation head surface 50S and the encapsulation back surface 50R face away from each other in the Z-direction. The first to fourth encapsulation side surfaces 50A to 50D connect the encapsulation head surface 50S and the encapsulation back surface 50R. The encapsulation head surface 50S defines the device head surface. The encapsulation back surface 50R defines the device back surface. The first to fourth encapsulation side surfaces 50A to 50D define the device side surfaces. The first encapsulation side surface 50A and the second encapsulation side surface 50B define two opposite end surfaces of the encapsulation resin 50 in the X-direction. The third encapsulation side surface 50C and the fourth encapsulation side surface 50D define two opposite end surfaces of the encapsulation resin 50 in the Y-direction. The encapsulation resin 50 is formed from, for example, a black epoxy resin.

As shown in FIGS. 2 and 3, in plan view, the terminals 30 are arranged along the first to fourth encapsulation side surfaces 50A to 50D. Each of the terminals 30 is partially exposed from the encapsulation resin 50. The terminal 30 includes a terminal portion 31 and a mount portion 32. In an example, the terminal portion 31 is integrated with the mount portion 32. That is, the terminal portion 31 and the mount portion 32 are integrally formed from the same metal material. The terminal 30 is formed from, for example, a material containing copper (Cu), aluminum (Al), or the like. In the present embodiment, the terminal 30 is formed from a material containing Cu. The terminal 30 is formed by etching a metal plate containing Cu.

The terminal portion 31 includes a terminal back surface 31R, a terminal head surface 31S, and a terminal side surface 31A. The terminal back surface 31R is exposed from the encapsulation back surface 50R of the encapsulation resin 50. The terminal head surface 31S faces away from the terminal back surface 31R. The terminal side surface 31A connects the terminal head surface 31S and the terminal back surface 31R. In plan view, the terminal portions 31 of the terminals 30 are located closer to the first to fourth encapsulation side surfaces 50A to 50D than the semiconductor chip 20 is. In other words, in plan view, the terminal portions 31 of the terminals 30 are located outward from the semiconductor chip 20. Accordingly, the semiconductor device 10 has a fan-out package structure.

In plan view, the terminal portions 31 of the terminals 30 are arranged along the first to fourth encapsulation side surfaces 50A to 50D. The terminal side surface 31A of each terminal portion 31 includes a side surface that is flush with a corresponding one of the first to fourth encapsulation side surfaces 50A to 50D. This flush side surface defines an exposed side surface 31AA exposed from the corresponding one of the first to fourth encapsulation side surfaces 50A to 50D.

A plating layer 34 is formed on both the terminal back surface 31R and the exposed side surface 31AA of each terminal portion 31. The plating layer 34 formed on the terminal back surface 31R projects from the encapsulation back surface 50R. The plating layer 34 formed on the exposed side surface 31AA projects from a corresponding one of the first to fourth encapsulation side surfaces 50A to 50D. In the present embodiment, the plating layer 34 formed on the terminal back surface 31R is integrated with the plating layer 34 formed on the exposed side surface 31AA. The plating layer 34 contains, for example, at least one of gold (Au), nickel (Ni), tin (Sn), and palladium (Pd).

The mount portion 32 extends from the terminal portion 31 in a direction orthogonal to the Z-direction. In plan view, the mount portion 32 extends from the terminal portion 31 toward the semiconductor chip 20. The mount portion 32 is thinner than the terminal portion 31. The mount portion 32 includes a mount head surface 32S facing the same direction as the terminal head surface 31S, and a mount back surface 32R facing away from the mount head surface 32S. In an example, the mount head surface 32S is flush with the terminal head surface 31S of the terminal portion 31. In plan view, the mount portion 32 is located at a position that overlaps the semiconductor chip 20. The mount portion 32 also includes a mount side surface 32A that connects the mount head surface 32S and the mount back surface 32R.

As shown in FIG. 5, the mount head surface 32S of the mount portion 32 is flat and is orthogonal to the Z-direction. In contrast, the mount back surface 32R is curved and bulged away from the semiconductor chip 20 in the Z-direction. In the example shown in FIG. 5, a curved surface extends between the mount back surface 32R and opposing parts of the mount side surface 32A, which face each other in a widthwise direction (Y-direction in FIG. 5) orthogonal to a direction in which the mount portion 32 extends. The opposing parts of the mount side surface 32A include a curved portion that is recessed in the Y-direction. This portion is located relatively close to the mount head surface 32S. A width WS (in FIG. 5, dimension in the Y-direction) of the mount head surface 32S of the mount portion 32 is greater than a width WR (in FIG. 5, dimension in the Y-direction) of the mount back surface 32R.

As shown in FIG. 2, the terminals 30 disposed at four corners of the encapsulation resin 50 in plan view (hereafter, “corner terminals 30C”) each include two terminal portions 31. The two terminal portions 31 of the corner terminal 30C are located at the same position in the X-direction, and are separated from each other in the Y-direction. These terminal portions 31 are joined by a terminal joint 33.

As shown in FIGS. 2 to 4, the semiconductor chip 20 is mounted on the mount portion 32 of each terminal 30. The semiconductor chip 20 has a rectangular plate shape and has a thickness-wise direction parallel to the Z-direction. The semiconductor chip 20 includes a chip head surface 20S and a chip back surface 20R, facing away from each other in the Z-direction. The chip head surface 20S faces the mount head surface 32S of the mount portion 32. The chip back surface 20R faces the same direction as the mount head surface 32S. The semiconductor chip 20 includes a semiconductor substrate 21 defining a chip main body. The semiconductor substrate 21 is formed from a material containing, for example, silicon (Si). The semiconductor chip 20 is, for example, a large scale integration (LSI) chip.

As shown in FIG. 4, the semiconductor substrate 21 includes a main body head surface 21S and a main body back surface 21R, facing away from each other in the Z-direction. The main body head surface 21S faces the same direction as the chip head surface 20S of the semiconductor chip 20. The main body back surface 21R faces the same direction as the chip back surface 20R. In the example shown in FIG. 4, the main body back surface 21R defines the chip back surface 20R.

As shown in FIGS. 4 and 5, the semiconductor chip 20 includes interconnects 22 arranged on the main body head surface 21S of the semiconductor substrate 21, and an insulating layer 23 covering the main body head surface 21S. The interconnects 22 are disposed on the semiconductor substrate 21 so as to face the mount portions 32 of the terminals 30 in the Z-direction. The insulating layer 23 includes openings that separately expose the interconnects 22 in the Z-direction. The interconnects 22 are formed from, for example, a material containing at least one of Al, Cu, Au, and titanium (Ti).

The semiconductor chip 20 includes chip terminals 24 formed on the chip head surface 20S. The chip terminals 24 are separately bonded to the interconnects 22. More specifically, the chip terminals 24 are bonded to the interconnects 22 exposed from the openings of the insulating layer 23. Each chip terminal 24 is cylindrical and extends from the interconnect 22 in the Z-direction.

As shown in FIG. 5, the chip terminal 24 includes a cylindrical terminal body 24A, and a barrier layer 24B formed on a distal end surface of the terminal body 24A. The chip terminal 24 contains, for example, at least one of Cu, Al, and Ti. The barrier layer 24B is, for example, a plating layer. The barrier layer 24B contains at least one of Au, Ni, and Pd. In an example, the barrier layer 24B is formed from a material containing Ni.

The mount head surface 32S of the mount portion 32 of each terminal 30 includes a barrier layer 35 formed in a region where the chip terminal 24 is connected. The region where the above-described chip terminal 24 is connected may also be referred to as a region where the semiconductor chip 20 is mounted. In other words, the barrier layer 35 defines part of the mount head surface 32S. In an example, the barrier layer 35 has a circular shape in plan view. The planar shape of the barrier layer 35 may be changed. The barrier layer 35 contains, for example, at least one of Ni and Ti.

The barrier layer 24B of each chip terminal 24 is bonded to the barrier layer 35 of a corresponding mount portion 32 by a conductive bonding material SD. This mounts the semiconductor chip 20 on the mount portions 32. The barrier layer 35 maintains the wettability of the conductive bonding material SD. In this manner, the chip terminals 24 are electrically connected to the mount portions 32 of the terminals 30. The conductive bonding material SD may be, for example, silver (Ag) paste or solder paste.

### Cover Layer

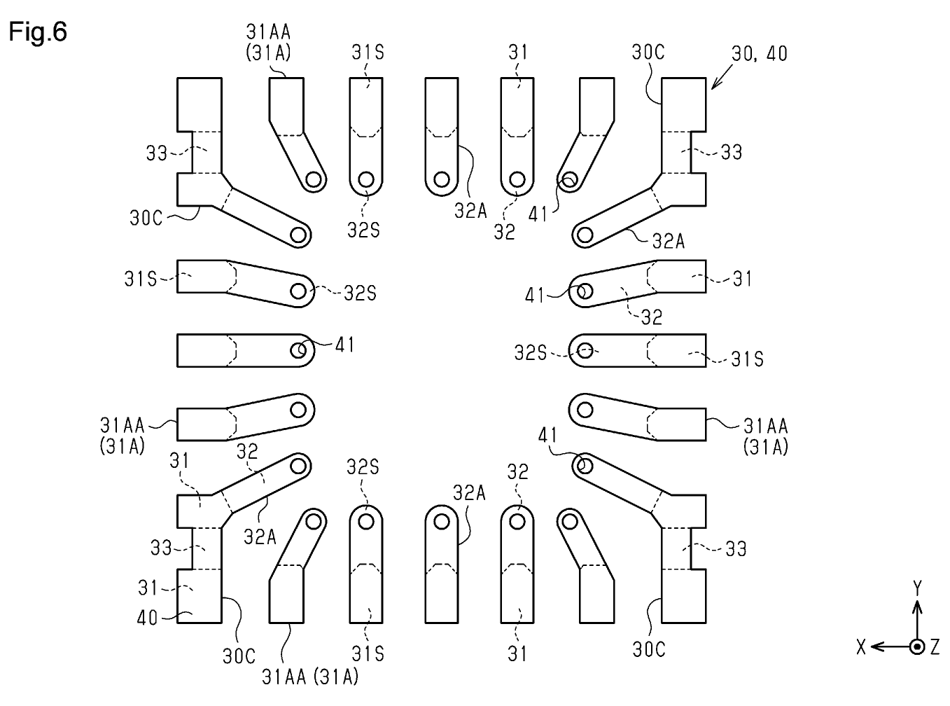

The structure of the cover layer 40 will now be described with reference to FIGS. 4 to 6. FIG. 6 is a schematic plan view showing the structures of the terminals 30 and the cover layer 40. In FIG. 6, a broken line indicates the boundary of the terminal portion 31 and the mount portion 32 in plan view

As shown in FIGS. 4 and 6, the cover layer 40 is formed on each terminal 30. The cover layer 40 is in contact with at least one of the mount head surface 32S of the mount portion 32 and the terminal head surface 31S of the terminal portion 31. In the present embodiment, the cover layer 40 is in contact with both the mount head surface 32S and the terminal head surface 31S.

The cover layer 40 extends, in a direction in which the mount portion 32 extends, from the terminal head surface 31S of the terminal portion 31 to an intermediate part located between the center of the mount portion 32 and a region where the semiconductor chip 20 is mounted. In an example, the cover layer 40 is disposed over the entire mount head surface 32S of the mount portion 32. The cover layer 40 includes an opening 41 that exposes the mount head surface 32S located in a region where the semiconductor chip 20 is mounted. The opening 41 exposes the entire barrier layer 35 (refer to FIG. 5). In an example, the cover layer 40 is formed on the entire terminal head surface 31S of the terminal portion 31.

As shown in FIG. 4, the cover layer 40 is not formed on the mount back surface 32R or the mount side surface 32A of the mount portion 32. That is, the mount back surface 32R of the mount portion 32 is in contact with the encapsulation resin 50. Also, the mount side surface 32A of the mount portion 32 is in contact with the encapsulation resin 50.

As shown in FIG. 6, in the corner terminal 30C, the cover layer 40 extends over the terminal head surface 31S of both of the two terminal portions 31, the head surface of the terminal joint 33, and the mount head surface 32S of the mount portion 32. That is, the cover layer 40 may be formed on an entire head surface of the corner terminal 30C. In contrast, the cover layer 40 is not formed on the terminal side surface 31A of both of the two terminal portions 31, the mount side surface 32A of the mount portion 32, or the side surface of the terminal joint 33. That is, the terminal side surface 31A of both of the two terminal portions 31, the mount side surface 32A of the mount portion 32, and the side surface of the terminal joint 33 are in contact with the encapsulation resin 50.

When the cover layer 40 is formed on the terminal head surface 31S of one of the two terminal portions 31, which is joined to the mount portion 32, the cover layer 40 does not have to be formed on the terminal head surface 31S of the other one of the two terminal portions 31. Furthermore, the cover layer 40 does not have to be formed on the terminal joint 33 joining the two terminal portions 31. That is, the terminal head surface 31S of the other one of the two terminal portions 31 and the terminal joint 33 may both be in contact with the encapsulation resin 50.

As shown in FIG. 5, a thickness TA of the cover layer 40 is less than a thickness TB of the mount portion 32. In an example, the thickness TA of the cover layer 40 is greater than the thickness of the barrier layer 35. In an example, the thickness TA of the cover layer 40 is in a range of 10 μm to 100 μm, inclusive. The thickness TA of the cover layer 40 may be changed.

The cover layer 40 has a lower linear expansion coefficient than the terminals 30. In an example, the cover layer 40 is formed from an insulation material. In an example, the cover layer 40 is formed from a resin material. Examples of a resin material include an epoxy resin, a polyimide resin, a phenol resin, and the like. The linear expansion coefficient may be measured in accordance with, for example, Japanese Industrial Standard (JIS) Z 2285:2003 and related standards. The linear expansion coefficient may be measured in accordance with, for example, JIS K 7197:2012 and related standards. The linear expansion coefficient may be measured in accordance with, for example, JIS R 1618:2002 and related standards. The linear expansion coefficient may be measured in accordance with, for example, American Society for Testing and Materials (ASTM) standard E831 “Standard Test Method for Linear Thermal Expansion of Solid Materials by Thermomechanical Analysis” and related standards.

Method for Manufacturing Semiconductor Device

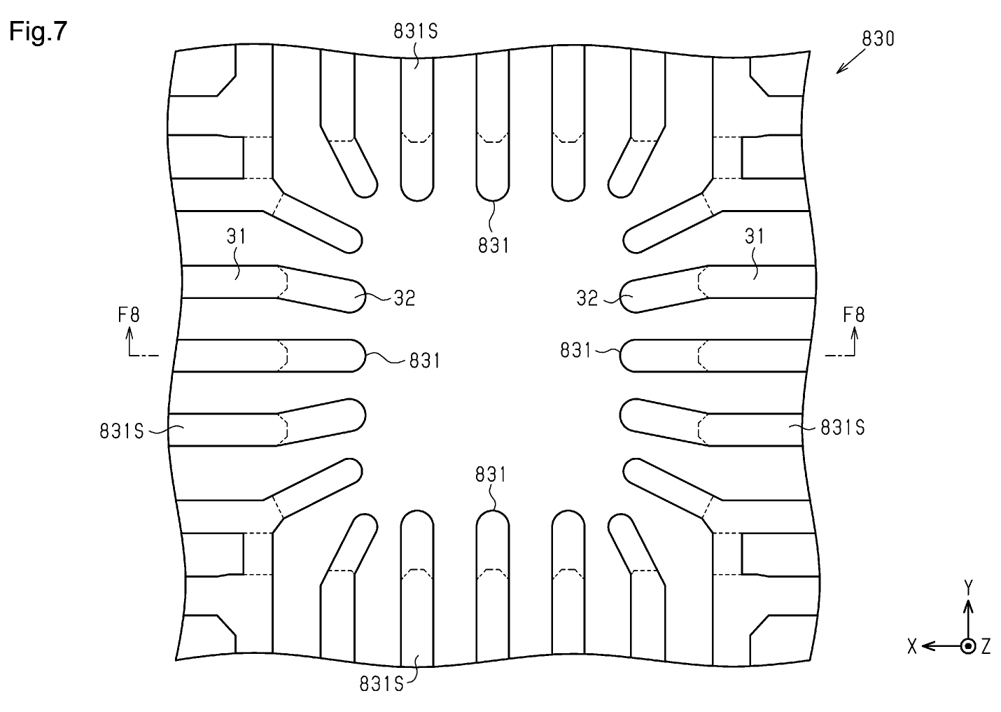

An example of a method for manufacturing the semiconductor device 10 will now be described with reference to FIGS. 7 to 13.

The method for manufacturing the semiconductor device 10 mainly includes a step of preparing the terminals 30, a step of forming the cover layer 40, a step of mounting the semiconductor chip 20 on the terminals 30, a step of forming the encapsulation resin 50, and a step of singulation.

FIG. 7 illustrates an example of the step of preparing the terminals 30. FIG. 7 is a schematic plan view showing the structure of part of a lead frame 830.

In the step of preparing the terminals 30, the metal lead frame 830 is prepared. The lead frame 830 has a flat plate shape and has a thickness-wise direction parallel to the Z-direction. The lead frame 830 is formed from a material containing, for example, Cu. The lead frame 830 includes lead portions 831 corresponding to the terminals 30, and a frame portion (not shown) supporting the lead portions 831. The lead frame 830 is formed by, for example, etching a metal plate containing Cu. The lead portions 831 each include a lead head surface 831S, and a lead back surface 831R, facing away from each other in the Z-direction. The lead portions 831 include the terminal portions 31 and the mount portions 32 of the terminals 30. In FIG. 7, in order to facilitate understanding, a broken line indicates the boundary of the terminal portion 31 and the mount portion 32.

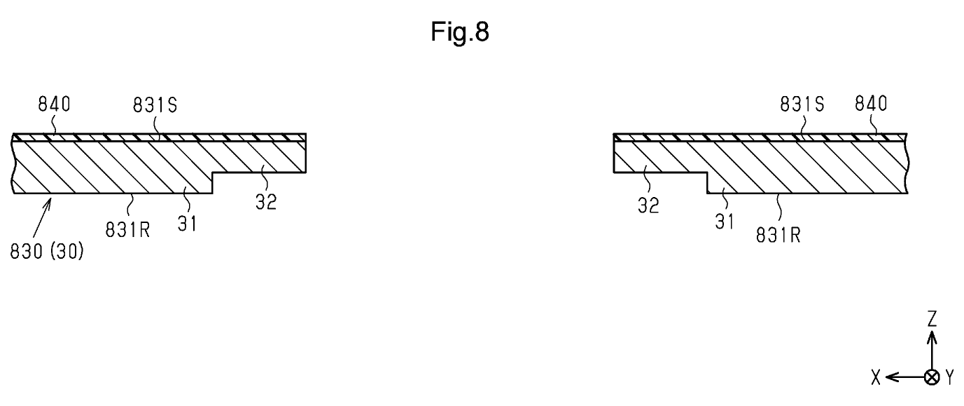

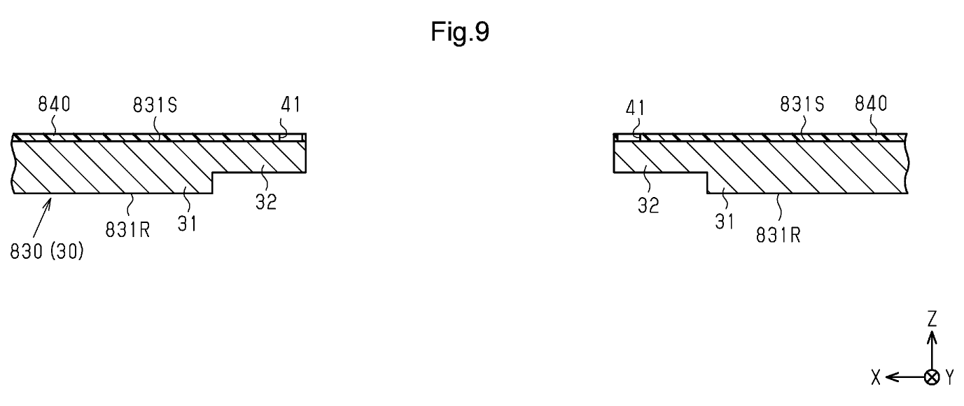

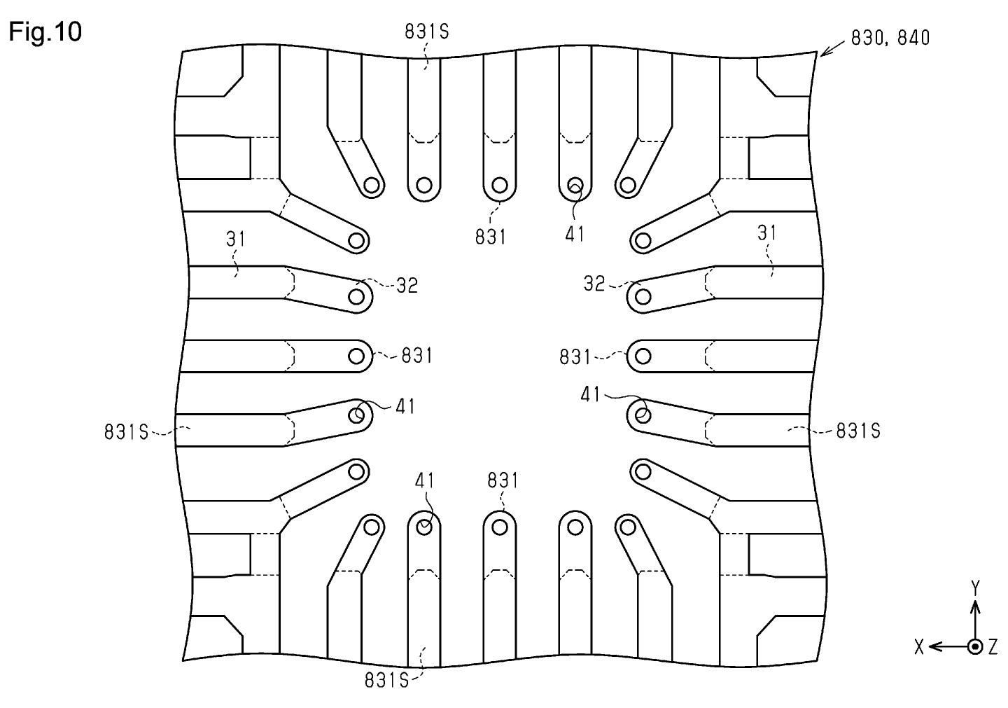

FIGS. 8 to 10 illustrate an example of the step of forming the cover layer 40. FIGS. 8 and 9 are schematic cross-sectional views taken along line F8-F8 shown in FIG. 7, showing the structure of the lead frame 830 and the cover layer 40. FIG. 10 is a schematic plan view showing the structure of the cover layer 40 and part of the lead frame 830.

As shown in FIG. 8, a resin material is applied to the lead head surface 831S of the lead portion 831 of the lead frame 830 to form a cover layer 840. In an example, screen printing is performed on the entire lead head surface 831S to form the cover layer 840.

As shown in FIG. 9, the cover layer 840 then underdoes exposure and development to form the opening 41 in the cover layer 840. As shown in FIG. 10, the cover layer 840 is formed on the entire lead head surface 831S of each lead portion 831 of the lead frame 830. The opening 41 is formed in a portion of the cover layer 840 that covers a distal end of the lead portion 831.

The range in which the cover layer 840 is formed on the lead head surface 831S may be changed. In an example, the cover layer 840 is formed on a portion of the lead head surface 831S that corresponds to the mount head surface 32S, and the cover layer 840 is not formed on a portion of the lead head surface 831S that corresponds to the terminal head surface 31S. In another example, the cover layer 840 is formed on a portion of the lead head surface 831S that corresponds to the terminal head surface 31S, and the cover layer 840 is not formed on a portion of the lead head surface 831S that corresponds to the mount head surface 32S. In another example, the cover layer 840 is formed on a portion of the lead head surface 831S that corresponds to the terminal head surface 31S of one of the two terminal portions 31 of the corner terminal 30C, which is joined to the mount portion 32, and the cover layer 840 is not formed on a portion of the lead head surface 831S that corresponds to the terminal head surface 31S of the other one of the two terminal portions 31.

In another example, when the cover layer 40 is formed on a portion of the lead head surface 831S that corresponds to the mount head surface 32S, and the cover layer 40 is not formed on a portion of the lead head surface 831S that corresponds to the terminal head surface 31S, the cover layer 840 may be formed on the entire lead head surface 831S and then removed from the portion of the lead head surface 831S that corresponds to the terminal head surface 31S.

In another example in which the cover layer 40 is formed on a portion of the lead head surface 831S that corresponds to the terminal head surface 31S, and the cover layer 40 is not formed on a portion of the lead head surface 831S that corresponds to the mount head surface 32S, the cover layer 840 may be formed on the entire lead head surface 831S and then removed from the portion of the lead head surface 831S that corresponds to the mount head surface 32S.

In another example in which the cover layer 40 is formed on the terminal head surface 31S of one of the two terminal portions 31 of the corner terminal 30C, which is joined to the mount portion 32, and the cover layer 40 is not formed on the terminal head surface 31S of the other one of the two terminal portions 31, the cover layer 40 is removed from the other one of the two terminal portions 31 and the terminal joint 33 of the corner terminal 30C.

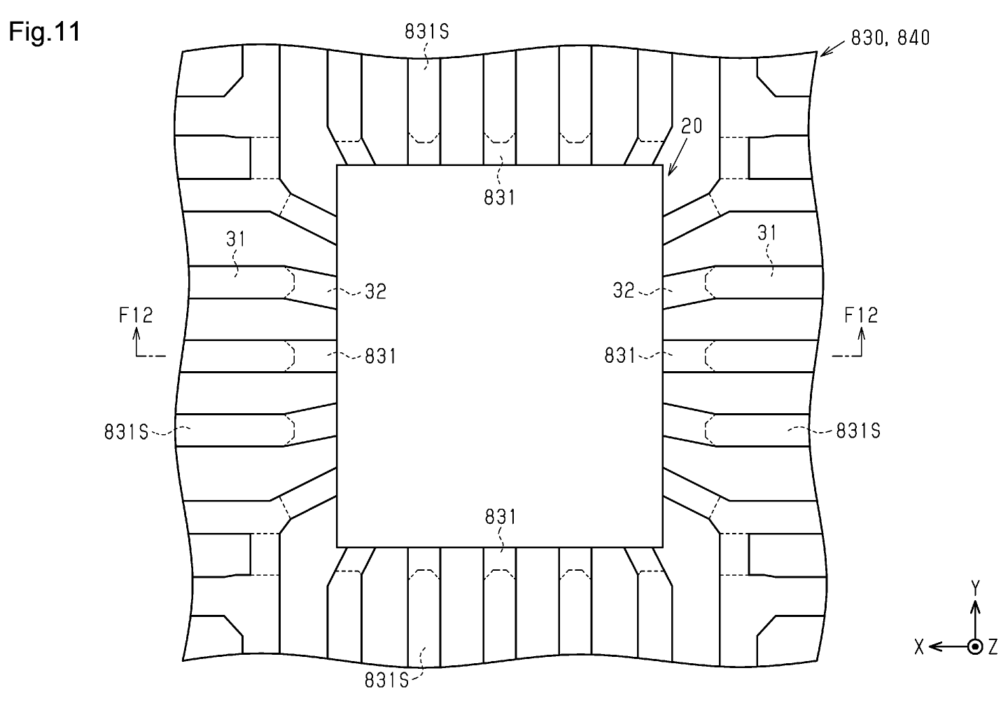

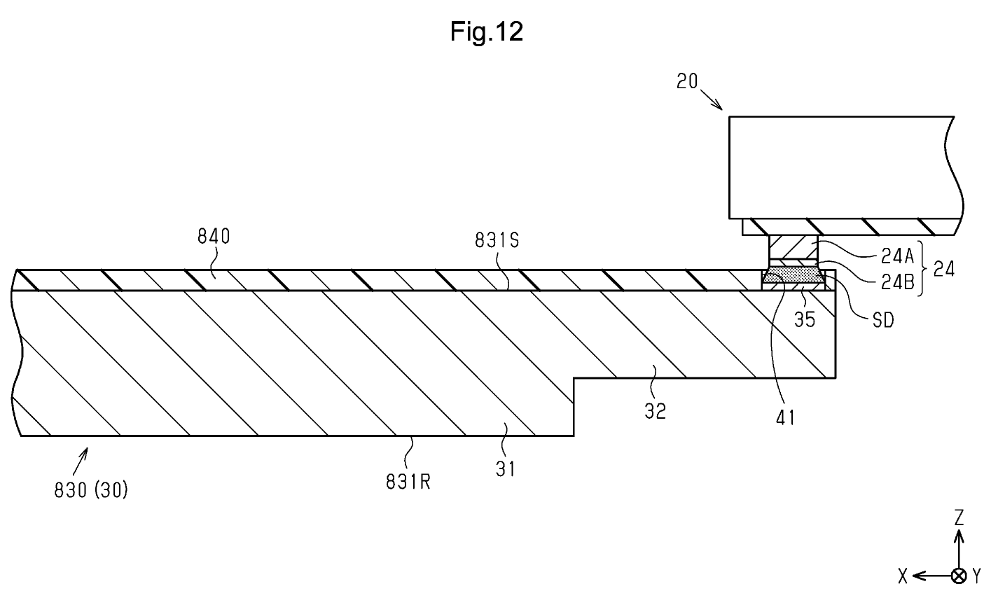

FIGS. 11 and 12 illustrate an example of a step of mounting the semiconductor chip 20 on the terminals 30. FIG. 11 is a schematic plan view showing the structure of the cover layer 40, the semiconductor chip 20, and part of the lead frame 830. FIG. 12 is a schematic cross-sectional view taken along line F12-F12 shown in FIG. 11, showing the structure the cover layer 40, the semiconductor chip 20, and part of the lead frame 830.

In the step of mounting the semiconductor chip 20 on the terminals 30, the chip terminals 24 of the semiconductor chip 20 are arranged on the terminals 30. More specifically, first, the conductive bonding material SD is applied to each chip terminal 24 of the semiconductor chip 20. Next, the chip terminal 24 of the semiconductor chip 20 is disposed in a region of the mount portion 32 of a corresponding terminal 30 in which the mount head surface 32S is exposed from the opening 41 of the cover layer 40. In other words, the chip terminal 24 of the semiconductor chip 20 is disposed in a region of the mount portion 32 in which the barrier layer 35 is exposed. Subsequently, the conductive bonding material SD is melted and then solidified by, for example, reflow soldering. As a result, the chip terminal 24 is bonded to the terminal 30. This electrically connects the chip terminals 24 to the terminals 30.

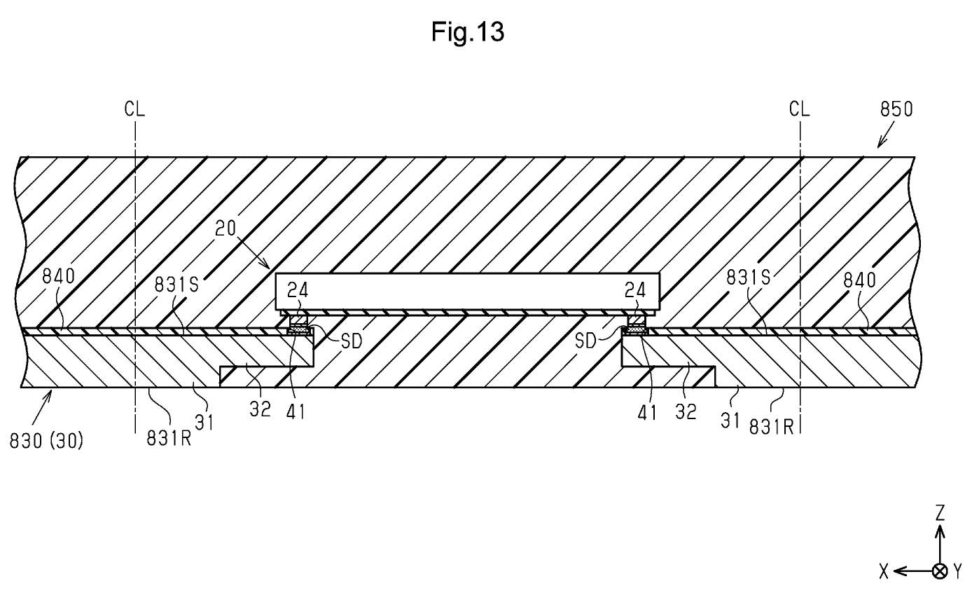

FIG. 13 illustrates the step of forming the encapsulation resin 50 and the step of singulation. FIG. 13 is a schematic cross-sectional view showing the structure of the cover layer 40, the semiconductor chip 20, the encapsulation resin 50, and part of the lead frame 830.

In the step of forming the encapsulation resin 50, a resin layer 850 is formed by, for example, transfer molding to cover the semiconductor chip 20, the lead frame 830, and the cover layers 40. The resin layer 850 includes multiple pieces of the encapsulation resin 50.

In the singulating step, the resin layer 850 and the lead frame 830 are cut along cutting lines CL shown in FIG. 13 by, for example, dicing. This obtains multiple pieces of the encapsulation resin 50 and multiple pieces of the terminals 30. The terminal side surfaces 31A (refer to FIG. 4) of the terminal portions 31 of the terminals 30 are exposed from the first to fourth encapsulation side surfaces 50A to 50D (refer to FIG. 2) of the encapsulation resin 50.

Although not shown in the drawings, the method for manufacturing the semiconductor device 10 includes a step of forming the plating layer 34 (refer to FIG. 4). The plating layer 34 is formed by, for example, electroless plating. As a result, the plating layer 34 is formed on the terminal back surface 31R and the exposed side surface 31AA of the terminal 30, which are exposed from the encapsulation resin 50. The semiconductor device 10 is manufactured by the above-described procedure.

### Operation of the Present Embodiment

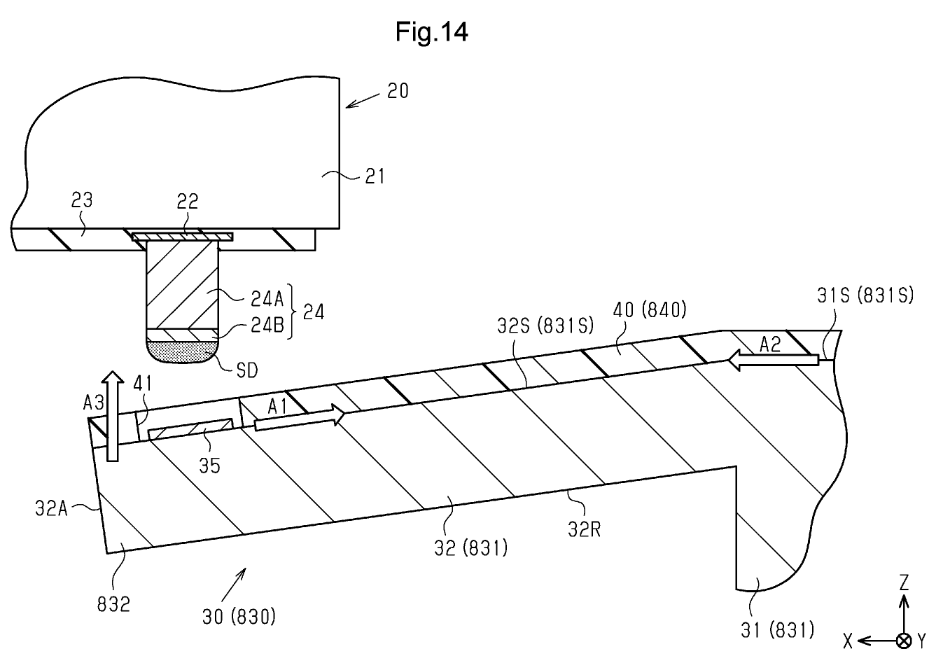

The operation of the semiconductor device 10 in accordance with the present embodiment will now be described with reference to FIG. 14.

In the step of preparing the terminals 30 in the manufacturing process of the semiconductor device 10, the lead frame 830 may have one or more lead portions 831 that are deformed away from the semiconductor chip 20. Accordingly, when the semiconductor chip 20 is disposed on the lead portions 831, some chip terminals 24 may be spaced apart from the corresponding lead portions 831.

In the present embodiment, the cover layer 840 is formed on the lead head surface 831S of the lead portion 831. Further, the cover layer 840 has a lower linear expansion coefficient than the lead portion 831. Accordingly, when reflow soldering is performed after the semiconductor chip 20 is disposed on the lead portions 831, thermal stress may be produced due to the difference in linear expansion coefficient between the cover layer 840 and the lead portion 831. As indicated by blank arrows A1 and A2 shown in FIG. 14, this thermal stress acts on the terminal head surface 31S and the mount head surface 32S of the lead portion 831, which are in contact with the cover layer 840, toward the center of the cover layer 840. As a result, as indicated by a blank arrow A3, the lead portion 831 deforms, such that its distal end 832 moves toward the semiconductor chip 20. That is, deformation of the lead portion 831 that separated the lead portion 831 away from the semiconductor chip 20 is corrected. This ensures the contact between the conductive bonding material SD and the chip terminal 24. As the conductive bonding material SD is cooled in such a state and solidifies, the chip terminal 24 is firmly joined to the lead portion 831. Thus, even when the lead portion 831 is spaced apart from the chip terminal 24, the cover layer 840 deforms the bent lead portion 831 toward the chip terminal 24 by a heating process during reflow soldering or the like. Therefore, the lead portion 831 is electrically connected to the chip terminal 24.

The lead frame 830 includes a frame portion (not shown) that supports the lead portion 831 of the lead frame 830. The lead portion 831 includes the mount portion 32 and the terminal portion 31. The mount portion 32 and the terminal portion 31 are connected to the frame portion. Both the mount portion 32 and the terminal portion 31 of the lead portion 831 thermally expand during reflow soldering, which is performed to mount the semiconductor chip 20. Accordingly, even when the cover layer 40 is formed on only the mount portion 32, thermal stress produced in the mount portion 32 deforms the terminal portion 31, such that the distal end 832 of the lead portion 831 moves toward the semiconductor chip 20. As a result, the lead portion 831 is electrically connected to the chip terminal 24. Similarly, even when the cover layer 40 is formed on only the terminal portion 31, thermal stress produced in the terminal portion 31 deforms the mount portion 32, such that the distal end 832 of the lead portion 831 moves toward the semiconductor chip 20. As a result, the lead portion 831 is electrically connected to the chip terminal 24.

### Advantages of the Present Embodiment

The semiconductor device 10 of the present embodiment has the following advantages.

(1) The semiconductor device 10 includes the terminals 30, the semiconductor chip 20 mounted on the terminals 30, and the encapsulation resin 50 encapsulating the terminals 30 and the semiconductor chip 20. The terminals 30 each include the terminal portion 31 and the mount portion 32. The terminal portion 31 includes the terminal back surface 31R exposed from the encapsulation resin 50, and the terminal head surface 31S opposite to the terminal back surface 31R. In plan view, the terminal portion 31 is located outward from the semiconductor chip 20. In plan view, the mount portion 32 extends from the terminal portion 31 toward the semiconductor chip 20. The mount portion 32 is thinner than the terminal portion 31. The mount portion 32 includes the mount head surface 32S facing the same direction as the terminal head surface 31S, and the mount back surface 32R opposite to the mount head surface 32S. The semiconductor chip 20 is mounted on the mount head surface 32S. The semiconductor device 10 includes the cover layer 40 that is in contact with at least one of the mount head surface 32S of the mount portion 32 and the terminal head surface 31S of the terminal portion 31. The cover layer 40 has a lower linear expansion coefficient than the terminals 30.

With this structure, thermal stress produced in the cover layer 40 and the terminal 30 by a heating process, such as reflow soldering or the like, moves the mount portion 32 of the terminal 30 toward the semiconductor chip 20. This deforms the mount portion 32, which is spaced apart from the chip terminal 24 of the semiconductor chip 20, toward the semiconductor chip 20. Accordingly, the mount portion 32 is electrically connected to the chip terminal 24. Therefore, even when the mount portion 32 is spaced apart from the chip terminal 24 before the heating process, the mount portion 32 can be electrically connected to the chip terminal 24.

(2) The mount back surface 32R of the mount portion 32 is in contact with the encapsulation resin 50.

With this structure, the cover layer 40 is not formed on the mount back surface 32R. Accordingly, thermal stress is readily produced in the mount head surface 32S, which is in contact with the cover layer 40, during a heating process such as reflow soldering or the like. Therefore, even when the mount portion 32 is spaced apart from the chip terminal 24 before the heating process, the mount portion 32 can be electrically connected to the chip terminal 24.

(3) The mount head surface 32S of the mount portion 32 is flush with the terminal head surface 31S of the terminal portion 31.

With this structure, as compared to a structure in which the mount head surface 32S and the terminal head surface 31S are located at different positions in the Z-direction, thermal stress produced in the cover layer 40, which extends over the mount head surface 32S and the terminal head surface 31S, readily moves the mount portion 32 toward the semiconductor chip 20 during a heating process, such as reflow soldering or the like.

(4) The cover layer 40 is disposed on the entire mount head surface 32S of the mount portion 32. The cover layer 40 includes the opening 41 that exposes the mount head surface 32S located in a region where the semiconductor chip 20 is mounted.

With this structure, thermal stress produced by a heating process, such as reflow soldering or the like, readily moves the mount portion 32, which is in contact with the cover layer 40, toward the semiconductor chip 20. Therefore, even when the mount portion 32 is spaced apart from the chip terminal 24 before the heating process, the mount portion 32 can be electrically connected to the chip terminal 24.

In addition, because the opening 41 exposes the mount head surface 32S, even when the cover layer 40 is disposed on the entire mount head surface 32S, the mount portion 32 is readily electrically connected to the semiconductor chip 20.

(5) The semiconductor chip 20 includes the chip terminal 24 electrically connected to the mount portion 32. The terminals 30 each include the barrier layer 35 formed in a region of the mount head surface 32S of the mount portion 32 in which the chip terminal 24 is connected. The opening 41 exposes the entire barrier layer 35.

With this structure, when the chip terminal 24 is bonded to the barrier layer 35 by, for example, the conductive bonding material SD, the conductive bonding material SD is disposed on the barrier layer 35 and is located in the opening 41. This avoids a situation in which the conductive bonding material SD spreads beyond the cover layer 40 to adjacent terminals 30.

(6) The cover layer 40 may extend, in a direction in which the mount portion 32 extends, from the terminal head surface 31S to an intermediate part located between the center of the mount portion 32 and a region where the semiconductor chip 20 is mounted.

With this structure, thermal stress produced by a heating process, such as reflow soldering or the like, readily moves the mount portion 32, which is in contact with the cover layer 40, toward the semiconductor chip 20. Therefore, even when the mount portion 32 is spaced apart from the chip terminal 24 before the heating process, the mount portion 32 can be electrically connected to the chip terminal 24.

(7) The cover layer 40 is formed on the entire terminal head surface 31S of the terminal portion 31.

With this structure, thermal stress produced by a heating process, such as reflow soldering or the like, readily moves the mount portion 32, which is in contact with the cover layer 40, toward the semiconductor chip 20. Therefore, even when the mount portion 32 is spaced apart from the chip terminal 24 before the heating process, the mount portion 32 can be electrically connected to the chip terminal 24.

(8) The mount portion 32 includes the mount side surface 32A that connects the mount head surface 32S and the mount back surface 32R. The mount side surface 32A is in contact with the encapsulation resin 50.

With this structure, as compared to a structure in which the cover layer 40 is formed on the mount side surface 32A, the cover layer 40 is decreased in volume. This reduces costs of the material of the cover layer 40. In addition, this structure does not require a step of forming the cover layer 40 on the mount side surface 32A, thereby simplifying the manufacturing process of the semiconductor device 10.

(9) The width WS of the mount head surface 32S is greater than the width WR of the mount back surface 32R.

With this structure, the cover layer 40 formed on the mount head surface 32S has a relatively large size in plan view. Accordingly, thermal stress produced by a heating process, such as reflow soldering or the like, readily moves the mount portion 32, which is in contact with the cover layer 40, toward the semiconductor chip 20. Therefore, even when the mount portion 32 is spaced apart from the chip terminal 24 before the heating process, the mount portion 32 can be electrically connected to the chip terminal 24.

(10) The cover layer 40 is formed from an insulation material.

With this structure, the difference in linear expansion coefficient between the metal terminals 30 and the cover layer 40 is relatively large. Accordingly, thermal stress produced by a heating process, such as reflow soldering or the like, readily moves the mount portion 32, which is in contact with the cover layer 40, toward the semiconductor chip 20. Therefore, even when the mount portion 32 is spaced apart from the chip terminal 24 before the heating process, the mount portion 32 can be electrically connected to the chip terminal 24. The same advantage may be obtained when the cover layer 40 is formed from an oxide film or a resin material.

(11) The thickness TA of the cover layer 40 is less than the thickness TB of the mount portion 32.

If the thickness TA of the cover layer 40 formed on the mount head surface 32S is relatively large, the rigidity of a portion of the mount portion 32 including the cover layer 40 is relatively high. Accordingly, even when thermal stress produced by a heating process, such as reflow soldering, acts to move the mount portion 32, which is in contact with the cover layer 40 of the mount head surface 32S, toward the semiconductor chip 20, the mount portion 32 may resist deformation from a position separated from the chip terminal 24 of the semiconductor chip 20 toward the semiconductor chip 20. In this respect, in the present embodiment, the thickness TA of the cover layer 40 is relatively small, such that the rigidity of the portion of the mount portion 32 including the cover layer 40 is not overly high. Accordingly, when thermal stress produced by a heating process acts to move the mount portion 32, which is in contact with the cover layer 40 of the mount head surface 32S, toward the semiconductor chip 20, the mount portion 32 readily deforms from a position separated from the chip terminal 24 of the semiconductor chip 20 toward the semiconductor chip 20. The same advantage may be obtained when the thickness TA of the cover layer 40 is in a range of 10 μm to 100 μm, inclusive.

(12) The method for manufacturing the semiconductor device 10 includes preparing the terminals 30, mounting the semiconductor chip 20 on the terminals 30, and forming the encapsulation resin 50 to encapsulate the terminals 30 and the semiconductor chip 20. The terminals 30 each include the terminal portion 31 and the mount portion 32. The terminal portion 31 includes the terminal back surface 31R exposed from the encapsulation resin 50, and the terminal head surface 31S opposite to the terminal back surface 31R. In plan view, the terminal portion 31 is located outward from the semiconductor chip 20. In plan view, the mount portion 32 extends from the terminal portion 31 toward the semiconductor chip 20. The mount portion 32 is thinner than the terminal portion 31. The mount portion 32 includes the mount head surface 32S facing the same direction as the terminal head surface 31S, and the mount back surface 32R opposite to the mount head surface 32S. The semiconductor chip 20 is mounted on the mount head surface 32S. The method for manufacturing the semiconductor device 10 includes, before the mounting the semiconductor chip 20, forming the cover layer 40 on the mount head surface 32S of the mount portion 32 and the terminal head surface 31S of the terminal portion 31. The cover layer 40 has a lower linear expansion coefficient than the terminals 30.

With this structure, thermal stress produced in the cover layer 40 and the terminal 30 by a heating process, such as reflow soldering or the like, moves the mount portion 32 of the terminal 30 toward the semiconductor chip 20. This deforms the mount portion 32, which is spaced apart from the chip terminal 24 of the semiconductor chip 20, toward the semiconductor chip 20. Accordingly, the mount portion 32 is electrically connected to the chip terminal 24. Therefore, even when the mount portion 32 is spaced apart from the chip terminal 24 before the heating process, the mount portion 32 can be electrically connected to the chip terminal 24.

(13) The mounting the semiconductor chip 20 includes reflow soldering.

With this structure, thermal stress produced in the cover layer 40 and the terminal 30 by reflow soldering moves the mount portion 32 of the terminal 30 toward the semiconductor chip 20. This deforms the mount portion 32, which is spaced apart from the chip terminal 24 of the semiconductor chip 20, toward the semiconductor chip 20. Accordingly, the mount portion 32 is electrically connected to the chip terminal 24. Therefore, even when the mount portion 32 is spaced apart from the chip terminal 24 before the reflow soldering, the mount portion 32 can be electrically connected to the chip terminal 24.

### Modified Examples

The above embodiment may be modified as described below. The modified examples described below may be combined as long as there is no technical contradiction.

The number of terminals 30 may be changed.

The range in which the cover layer 40 is formed may be changed. In an example, the cover layer 40 is not formed on the terminal head surface 31S of the terminal portion 31, and the cover layer 40 is formed on the mount head surface 32S of the mount portion 32. In this case, the terminal head surface 31S is in contact with the encapsulation resin 50. In another example, the cover layer 40 is not formed on the mount head surface 32S of the mount portion 32, and the cover layer 40 is formed on the terminal head surface 31S of the terminal portion 31. In this case, the mount head surface 32S is in contact with the encapsulation resin 50. In another example, the cover layer 40 may be formed on part of the mount head surface 32S. Specifically, the cover layer 40 may extend from an end of the mount head surface 32S located relatively close to the terminal head surface 31S to the center of the mount head surface 32S in the lengthwise direction. That is, the cover layer 40 does not have to be formed on a distal end of the mount portion 32 where the chip terminal 24 of the semiconductor chip 20 is bonded. In another example, the cover layer 40 may be formed on part of the terminal head surface 31S of the terminal portion 31.

The cover layer 40 may be formed on the mount side surface 32A of the mount portion 32.

The cover layer 40 may be formed on the terminal side surface 31A of the terminal portion 31, except for on the exposed side surface 31AA.

The shape of the mount portion 32 of the terminal 30 may be changed. In an example, the width WS of the mount head surface 32S may be less than or equal to the width WR of the mount back surface 32R.

The cover layer 40 may be formed from a metal material having a lower linear expansion coefficient than the terminals 30.

The thickness TA of the cover layer 40 may be greater than or equal to the thickness TB of the mount portion 32.

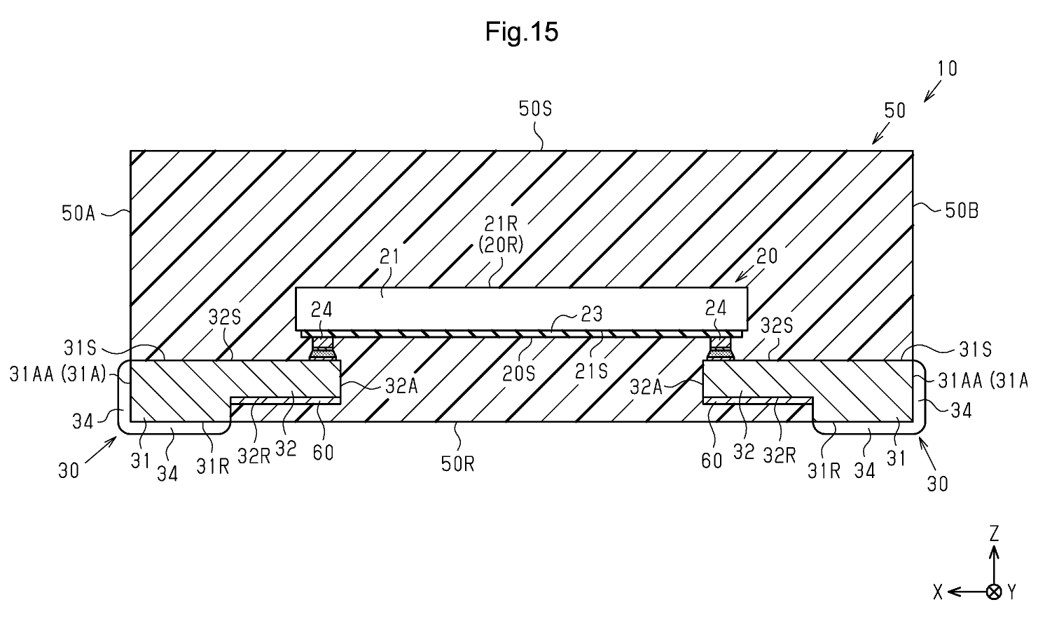

As shown in FIG. 15, the semiconductor device 10 may include a back surface cover layer 60 formed on the mount back surface 32R of the mount portion 32. In this case, the cover layer 40 may be omitted from the semiconductor device 10.

The back surface cover layer 60 has a lower linear expansion coefficient than the terminals 30. In an example, when the terminals 30 are formed from Cu, the back surface cover layer 60 may be formed from at least one of Al, Ag, and lead (Pb). The back surface cover layer 60 is formed on, for example, the entire mount back surface 32R. The back surface cover layer 60 may be formed on part of the mount back surface 32R. The back surface cover layer 60 may be thinner than the mount portion 32. The back surface cover layer 60 has a thickness, for example, in a range of 10 μm to 100 μm, inclusive.

With this structure, due to the difference in linear expansion coefficient between the terminal 30 and the back surface cover layer 60, thermal stress may be produced in the mount back surface 32R of the mount portion 32 by a heating process, such as reflow soldering or the like. This thermal stress acts in a direction opposite to that of the thermal stress indicated by the blank arrows A1 and A2 shown in FIG. 14. Accordingly, deformation that separated the mount portion 32 away from the semiconductor chip 20 is corrected. Therefore, even when the mount portion 32 is spaced apart from the chip terminal 24 before the heating process, the mount portion 32 can be electrically connected to the chip terminal 24.

In the modified example shown in FIG. 15, the semiconductor device 10 may include the cover layer 40 extending over the terminal head surface 31S of the terminal portion 31 and the mount head surface 32S of the mount portion 32 of the terminal 30. This cover layer 40 is the same as that of the above-described embodiment.

With this structure, thermal stress produced in the back surface cover layer 60, the cover layer 40, and the terminal 30 by a heating process, such as reflow soldering or the like, moves the mount portion 32 toward the semiconductor chip 20. Accordingly, deformation of the mount portion 32 that separated the mount portion 32 away from the semiconductor chip 20 is corrected. Therefore, even when the mount portion 32 is spaced apart from the chip terminal 24 before the heating process, the mount portion 32 can be electrically connected to the chip terminal 24.

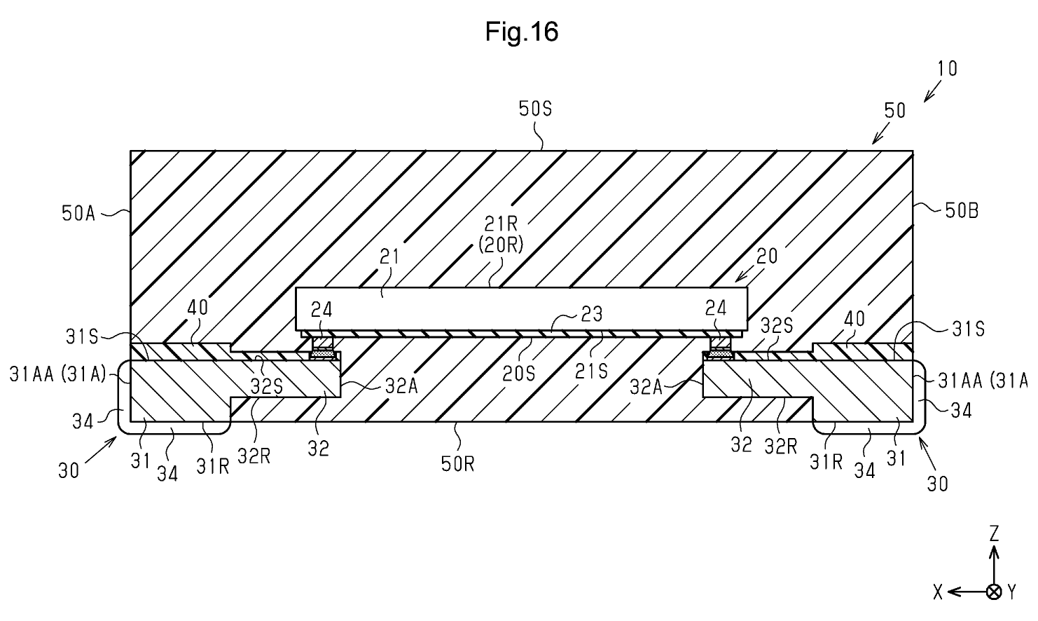

The thickness of the cover layer 40 may be changed. In the example shown in FIG. 16, the thickness of a portion of the cover layer 40 that corresponds to the terminal portion 31 may be greater than the thickness of a portion of the cover layer 40 that corresponds to the mount portion 32. Although not shown in the drawings, the thickness of a portion of the cover layer 40 that corresponds to the mount portion 32 may be greater than the thickness of a portion of the cover layer 40 that corresponds to the terminal portion 31.

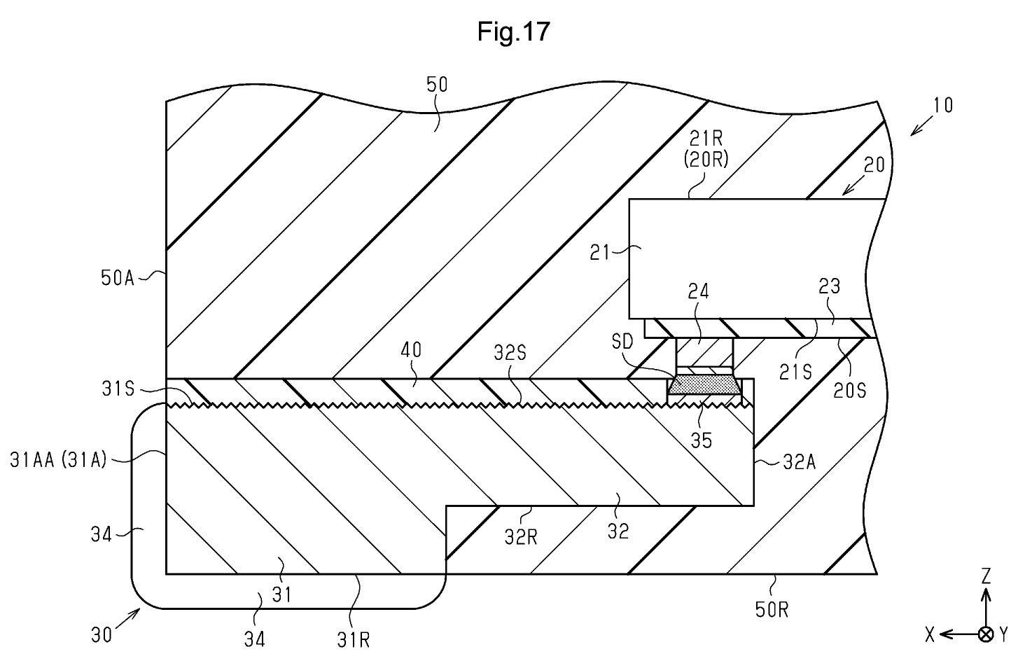

As shown in FIG. 17, the mount head surface 32S of the mount portion 32 of the terminal 30 may be rougher than the mount back surface 32R. In an example, the mount head surface 32S may have a greater arithmetic average roughness (Ra) than the mount back surface 32R. This improves the adhesion between the cover layer 40, which corresponds to the mount portion 32, and the mount head surface 32S. The arithmetic average roughness may be in accordance with JIS B 0601:2013. The arithmetic average roughness may be measured in accordance with, for example, JIS B 0633:2001 and related standards. The arithmetic average roughness may be measured in accordance with, for example, JIS B 0681-6:2014 and related standards.

The mount head surface 32S of the mount portion 32 may be rougher than the mount side surface 32A. In an example, the mount head surface 32S may have a greater arithmetic average roughness of the mount side surface 32A.

Furthermore, the terminal head surface 31S of the terminal portion 31 may be rougher than the terminal back surface 31R. In an example, the terminal head surface 31S may have a greater arithmetic average roughness of the terminal back surface 31R. This improves the adhesion between the cover layer 40, which corresponds to the terminal portion 31, and the terminal head surface 31S.

The terminal head surface 31S of the terminal portion 31 may be rougher than the terminal side surface 31A. In an example, the terminal head surface 31S may have a greater arithmetic average roughness than the terminal side surface 31A. The terminal head surface 31S may be rougher than the exposed side surface 31AA of the terminal side surface 31A. In an example, the terminal head surface 31S may have a greater arithmetic average roughness than the exposed side surface 31AA. The surfaces may be roughened by, for example, sandblasting.

In this manner, when the adhesion between the cover layer 40 and the terminal 30 is improved, thermal stress produced in the cover layer 40 and the terminal 30 readily acts on the mount portion 32. This readily deforms the mount portion 32, which is spaced apart from the chip terminal 24 of the semiconductor chip 20, toward the semiconductor chip 20 during a heating process, such as reflow soldering or the like. Accordingly, the mount portion 32 is readily electrically connected to the chip terminal 24. Therefore, even when the mount portion 32 is spaced apart from the chip terminal 24 before the heating process, the mount portion 32 can be electrically connected to the chip terminal 24.

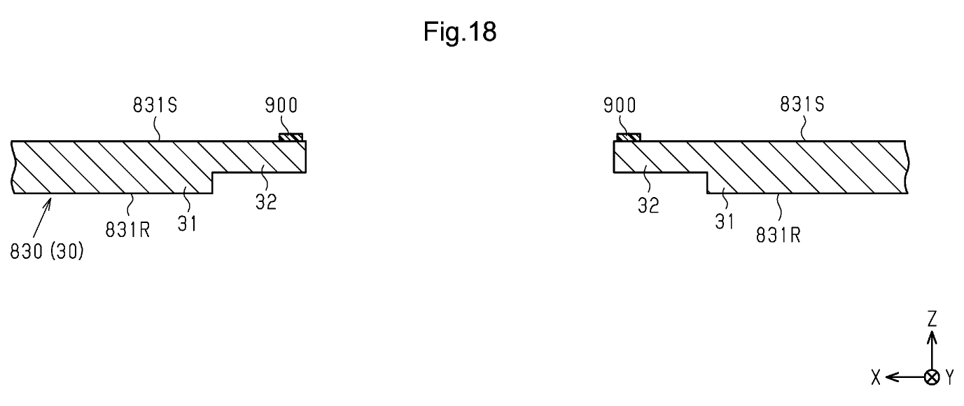

In the method for manufacturing the semiconductor device 10, the step of forming the cover layer 40 may be changed. FIGS. 18 to 20 are schematic cross-sectional views illustrating an example of the step of forming the cover layer 40.

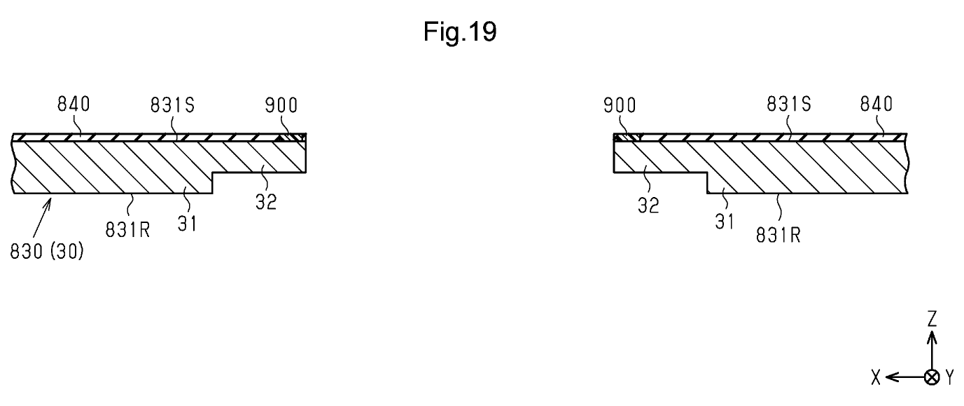

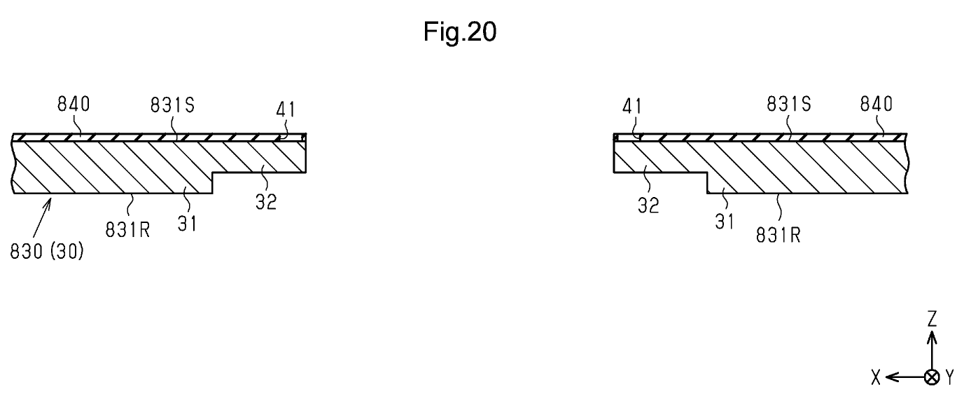

As shown in FIG. 18, a resist 900 is applied to a region of the lead head surface 831S of the lead portion 831 of the lead frame 830 in which the semiconductor chip 20 is to be mounted. As shown in FIG. 19, the cover layer 840 is then deposited on the lead head surface 831S, except for on a portion that corresponds to the resist 900, by sputtering or chemical vapor deposition (CVD), for example. The cover layer 840 is formed on a portion of the lead head surface 831S that corresponds to at least one of the mount head surface 32S and the terminal head surface 31S. In the example shown in FIG. 19, the cover layer 840 is formed on a portion of the lead head surface 831S that corresponds to both the mount head surface 32S and the terminal head surface 31S. As shown in FIG. 20, the resist 900 is then removed by etching, for example. This forms the opening 41 in the cover layer 840. The cover layer 840 is formed from, for example, an insulation material.

The range in which the cover layer 840 is formed on the lead head surface 831S may be changed. In an example, the cover layer 840 is formed on a portion of the lead head surface 831S that corresponds to the mount head surface 32S, and the cover layer 840 is not formed on a portion of the lead head surface 831S that corresponds to the terminal head surface 31S. In another example, the cover layer 840 is formed on a portion of the lead head surface 831S that corresponds to the terminal head surface 31S, and the cover layer 840 is not formed on a portion of the lead head surface 831S that corresponds to the mount head surface 32S.

Various examples described in this specification may be combined as long as there is no technical contradiction.

In the present disclosure, the term “on” includes the meaning of “above” in addition to the meaning of “on” unless otherwise described in the context. Accordingly, for example, a phrase such as “first element disposed on second element” may mean that the first element is directly located on the second element in one embodiment and that the first element is located above the second element without contacting the second element in another embodiment. Therefore, the term “on” does not exclude a structure in which another element is formed between the first element and the second element.

The Z-direction as referred to in this disclosure does not have to be the vertical direction, and does not have to exactly coincide with the vertical direction. Accordingly, in the various structures of the present disclosure, “up” and “down” in the Z-direction as referred to in this specification are not limited to “up” and “down” in the vertical direction. For example, the vertical direction may be the X-direction or the Y-direction.

### Clauses

Technical concepts that can be understood from the present disclosure will now be described. Reference characters used in the described embodiment are added to corresponding elements in the clauses to aid understanding without any intention to impose limitations on these elements. The reference characters are given as examples to aid understanding, and are not intended to limit elements to the elements denoted by the reference characters.

Clause 1

A semiconductor device (10), including:

terminals (30);

a semiconductor chip (20) mounted on the terminals (30); and

an encapsulation resin (50) encapsulating the terminals (30) and the semiconductor chip (20), in which

the terminals (30) each include

a terminal portion (31) including a terminal back surface (31R) exposed from the encapsulation resin (50), and a terminal head surface (31S) opposite to the terminal back surface (31R), the terminal portion (31) being located outward from the semiconductor chip (20) as viewed in a thickness-wise direction (Z-direction) of the semiconductor chip (20), and

a mount portion (32) extending from the terminal portion (31) toward the semiconductor chip (20) as viewed in the thickness-wise direction (Z-direction), the mount portion (32) being thinner than the terminal portion (31), the mount portion (32) including a mount head surface (32S) facing a same direction as the terminal head surface (31S), and a mount back surface (32R) opposite to the mount head surface (32S), the semiconductor chip (20) being mounted on the mount head surface (32S),

the semiconductor device (10) includes a cover layer (40) contacting at least one of the mount head surface (32S) of the mount portion (32) and the terminal head surface (31S) of the terminal portion (31), and

the cover layer (40) has a lower linear expansion coefficient than the terminals (30).

Clause 2

The semiconductor device according to clause 1, in which the mount back surface (32R) of the mount portion (32) is in contact with the encapsulation resin (50).

Clause 3

The semiconductor device according to clause 1 or 2, in which the mount head surface (32S) of the mount portion (32) is flush with the terminal head surface (31S) of the terminal portion (31).

Clause 4

The semiconductor device according to any one of clauses 1 to 3, in which

the cover layer (40) is disposed over an entirety of the mount head surface (32S) of the mount portion (32), and

the cover layer (40) includes an opening (41) exposing the mount head surface (32S) located in a region in which the semiconductor chip (20) is mounted.

Clause 5

The semiconductor device according to clause 4, in which

the semiconductor chip (20) includes a chip terminal (24) electrically connected to the mount portion (32),

the terminals (30) each include a barrier layer (35) formed in a region of the mount head surface (32S) of the mount portion (32) in which the chip terminal (24) is connected, and

the opening (41) exposes an entirety of the barrier layer (35).

Clause 6

The semiconductor device according to clause 1 or 2, in which the cover layer (40) extends, in a direction in which the mount portion (32) extends, from the terminal head surface (31S) to an intermediate part located between a center of the mount portion (32) and a region in which the semiconductor chip (20) is mounted.

Clause 7

The semiconductor device according to any one of clauses 1 to 6, in which the cover layer (40) is formed on an entirety of the terminal head surface (31S) of the terminal portion (31).

Clause 8

The semiconductor device according to any one of clauses 1 to 7, in which

the mount portion (32) includes a mount side surface (32A) connecting the mount head surface (32S) and the mount back surface (32R), and

the mount side surface (32A) is in contact with the encapsulation resin (50).

Clause 9

The semiconductor device according to any one of clauses 1 to 8, in which a width (WS) of the mount head surface (32S) is greater than a width (WR) of the mount back surface (32R).

Clause 10

The semiconductor device according to any one of clauses 1 to 9, in which the cover layer (40) is formed from an insulation material.

Clause 11

The semiconductor device according to clause 10, in which the cover layer (40) is formed from an oxide film or a resin material.

Clause 12

The semiconductor device according to any one of clauses 1 to 11, in which a thickness (TA) of the cover layer (40) is less than a thickness (TB) of the mount portion (32).

Clause 13

The semiconductor device according to any one of clauses 1 to 12, in which the cover layer (40) has a thickness (TA) in a range of 10 μm to 100 μm, inclusive.

Clause 14

The semiconductor device according to any one of clauses 1 to 13, in which the mount head surface (32S) is rougher than the mount back surface (32R).

Clause 15

The semiconductor device according to any one of clauses 1 to 14, further including a back surface cover layer (60) formed on the mount back surface (32R) of the mount portion (32), the back surface cover layer (60) having a higher linear expansion coefficient than the terminals (30).

Clause 16

A semiconductor device (10), including:

terminals (30);

a semiconductor chip (20) mounted on the terminals (30); and

an encapsulation resin (50) encapsulating the terminals (30) and the semiconductor chip (20), in which

the terminals (30) each include

a terminal portion (31) including a terminal back surface (31R) exposed from the encapsulation resin (50), and a terminal head surface (31S) opposite to the terminal back surface (31R), the terminal portion (31) being located outward from the semiconductor chip (20) as viewed in a thickness-wise direction (Z-direction) of the semiconductor chip (20), and

a mount portion (32) extending from the terminal portion (31) toward the semiconductor chip (20) as viewed in the thickness-wise direction (Z-direction), the mount portion (32) being thinner than the terminal portion (31), the mount portion (32) including a mount head surface (32S) facing a same direction as the terminal head surface (31S), and a mount back surface (32R) opposite to the mount head surface (32S), the semiconductor chip (20) being mounted on the mount head surface (32S),

the semiconductor device (10) includes a back surface cover layer (60) formed on the mount back surface (32R) of the mount portion (32), and

the back surface cover layer (60) has a higher linear expansion coefficient than the terminals (30).

Clause 17

A method for manufacturing a semiconductor device, the method including:

preparing terminals (30/830);

mounting a semiconductor chip (20) on the terminals (30/830); and

forming an encapsulation resin (50/850) to encapsulate the terminals (30/830) and the semiconductor chip (20), in which

the terminals (30/830) each include

a terminal portion (31) including a terminal back surface (31R) exposed from the encapsulation resin (50/850), and a terminal head surface (31S) opposite to the terminal back surface (31R), the terminal portion (31) being located outward from the semiconductor chip (20) as viewed in a thickness-wise direction (Z-direction) of the semiconductor chip (20), and

a mount portion (32) extending from the terminal portion (31) toward the semiconductor chip (20) as viewed in the thickness-wise direction (Z-direction), the mount portion (32) being thinner than the terminal portion (31), the mount portion (32) including a mount head surface (32S) facing a same direction as the terminal head surface (31S), and a mount back surface (32R) opposite to the mount head surface (32S), the semiconductor chip (20) being mounted on the mount head surface (32S),

the method includes, before the mounting the semiconductor chip (20), forming a cover layer (40) on at least one of the mount head surface (32S) of the mount portion (32) and the terminal head surface (31S) of the terminal portion (31), and

the cover layer (40) has a lower linear expansion coefficient than the terminals (30/830).

Clause 18

The method according to clause 17, in which the mounting the semiconductor chip (20) includes reflow process.

Clause 19

The method according to clause 17 or 18, in which the forming the cover layer (40) includes applying a resin material to at least one of the mount head surface (32S) and the terminal head surface (31S).

Clause 20

The method according to clause 17 or 18, in which the forming the cover layer (40) includes depositing the cover layer (40) on at least one of the mount head surface (32S) and the terminal head surface (31S).

Clause 21

A method for manufacturing a semiconductor device, the method including:

preparing terminals (30/830);

mounting a semiconductor chip (20) on the terminals (30/830); and

forming an encapsulation resin (50/850) to encapsulate the terminals (30/830) and the semiconductor chip (20), in which

the terminals (30/830) each include

a terminal portion (31) including a terminal back surface (31R) exposed from the encapsulation resin (50/850), and a terminal head surface (31S) opposite to the terminal back surface (31R), the terminal portion (31) being located outward from the semiconductor chip (20) as viewed in a thickness-wise direction (Z-direction) of the semiconductor chip (20), and

a mount portion (32) extending from the terminal portion (31) toward the semiconductor chip (20) as viewed in the thickness-wise direction (Z-direction), the mount portion (32) being thinner than the terminal portion (31), the mount portion (32) including a mount head surface (32S) facing a same direction as the terminal head surface (31S), and a mount back surface (32R) opposite to the mount head surface (32S), the semiconductor chip (20) being mounted on the mount head surface (32S),

the method includes, before the mounting the semiconductor chip (20), forming a back surface cover layer (60) on the mount back surface (32R) of the mount portion (32), and

the back surface cover layer (60) has a higher linear expansion coefficient than the terminals (30).

Clause 22

The semiconductor device according to any one of clauses 1 to 15, in which

the cover layer (40) extends over the terminal head surface (31S) and the mount head surface (32S), and

a portion of the cover layer (40) formed on the terminal head surface (31S) is thicker than a portion of the cover layer (40) formed on the mount head surface (32S).

The above descriptions are merely exemplary. One skilled in the art would recognize the potential for a wide variety of combinations and substitutions of the elements and methods (manufacturing processes) in addition to those illustrated to describe the techniques of this disclosure. Any substitutions, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
terminals;
a semiconductor chip mounted on the terminals; and
an encapsulation resin encapsulating the terminals and the semiconductor chip, wherein
the terminals each include
a terminal portion including a terminal back surface exposed from the encapsulation resin, and a terminal head surface opposite to the terminal back surface, the terminal portion being located outward from the semiconductor chip as viewed in a thickness-wise direction of the semiconductor chip, and
a mount portion extending from the terminal portion toward the semiconductor chip as viewed in the thickness-wise direction, the mount portion being thinner than the terminal portion, the mount portion including a mount head surface facing a same direction as the terminal head surface, and a mount back surface opposite to the mount head surface, the semiconductor chip being mounted on the mount head surface,
the semiconductor device includes a cover layer contacting at least one of the mount head surface of the mount portion and the terminal head surface of the terminal portion, and
the cover layer has a lower linear expansion coefficient than the terminals.

2. The semiconductor device according to claim 1, wherein the mount back surface of the mount portion is in contact with the encapsulation resin.

3. The semiconductor device according to claim 1, wherein the mount head surface of the mount portion is flush with the terminal head surface of the terminal portion.

4. The semiconductor device according to claim 1, wherein
the cover layer is disposed over an entirety of the mount head surface of the mount portion, and
the cover layer includes an opening exposing the mount head surface located in a region where the semiconductor chip is mounted.

5. The semiconductor device according to claim 4, wherein
the semiconductor chip includes a chip terminal electrically connected to the mount portion,
the terminals each include a barrier layer formed in a region of the mount head surface of the mount portion where the chip terminal is connected, and
the opening exposes an entirety of the barrier layer.

6. The semiconductor device according to claim 1, wherein the cover layer extends, in a direction in which the mount portion extends, from the terminal head surface to an intermediate part located between a center of the mount portion and a region where the semiconductor chip is mounted.

7. The semiconductor device according to claim 1, wherein the cover layer is formed on an entirety of the terminal head surface of the terminal portion.

8. The semiconductor device according to claim 1, wherein
the mount portion includes a mount side surface connecting the mount head surface and the mount back surface, and
the mount side surface is in contact with the encapsulation resin.

9. The semiconductor device according to claim 1, wherein a width of the mount head surface is greater than a width of the mount back surface.

10. The semiconductor device according to claim 1, wherein the cover layer is formed from an insulation material.

11. The semiconductor device according to claim 10, wherein the cover layer is formed from an oxide film or a resin material.

12. The semiconductor device according to claim 1, wherein a thickness of the cover layer is less than a thickness of the mount portion.

13. The semiconductor device according to claim 1, wherein the cover layer has a thickness in a range of 10 μm to 100 μm, inclusive.

14. The semiconductor device according to claim 1, wherein the mount head surface is rougher than the mount back surface.

15. The semiconductor device according to claim 1, further comprising a back surface cover layer formed on the mount back surface of the mount portion, the back surface cover layer having a higher linear expansion coefficient than the terminals.

16. A semiconductor device, comprising:
terminals;
a semiconductor chip mounted on the terminals; and
an encapsulation resin encapsulating the terminals and the semiconductor chip, wherein
the terminals each include
a terminal portion including a terminal back surface exposed from the encapsulation resin, and a terminal head surface opposite to the terminal back surface, the terminal portion being located outward from the semiconductor chip as viewed in a thickness-wise direction of the semiconductor chip, and
a mount portion extending from the terminal portion toward the semiconductor chip as viewed in the thickness-wise direction, the mount portion being thinner than the terminal portion, the mount portion including a mount head surface facing a same direction as the terminal head surface, and a mount back surface opposite to the mount head surface, the semiconductor chip being mounted on the mount head surface,
the semiconductor device includes a back surface cover layer formed on the mount back surface of the mount portion, and
the back surface cover layer has a higher linear expansion coefficient than the terminals.

17. A method for manufacturing a semiconductor device, the method comprising:
preparing terminals;
mounting a semiconductor chip on the terminals; and
forming an encapsulation resin to encapsulate the terminals and the semiconductor chip, wherein
the terminals each include
a terminal portion including a terminal back surface exposed from the encapsulation resin, and a terminal head surface opposite to the terminal back surface, the terminal portion being located outward from the semiconductor chip as viewed in a thickness-wise direction of the semiconductor chip, and
a mount portion extending from the terminal portion toward the semiconductor chip as viewed in the thickness-wise direction, the mount portion being thinner than the terminal portion, the mount portion including a mount head surface facing a same direction as the terminal head surface, and a mount back surface opposite to the mount head surface, the semiconductor chip being mounted on the mount head surface,
the method includes, before the mounting the semiconductor chip, forming a cover layer on at least one of the mount head surface of the mount portion and the terminal head surface of the terminal portion, and
the cover layer has a lower linear expansion coefficient than the terminals.

18. The method according to claim 17, wherein the mounting the semiconductor chip includes reflow process.

19. The method according to claim 17, wherein the forming the cover layer includes applying a resin material to at least one of the mount head surface and the terminal head surface.

20. The method according to claim 17, wherein the forming the cover layer includes depositing the cover layer on at least one of the mount head surface and the terminal head surface.
